(19) United States
(12) Patent Application Publication
(10) Pub. No.: US 2025/0133939 A1
(43) Pub. Date: Apr. 24, 2025

(54) DISPLAY DEVICE, WEARABLE ELECTRONIC DEVICE, AND METHOD OF MANUFACTURING DISPLAY DEVICE

(71) Applicant: Samsung Display Co., Ltd., Yongin-Si (KR)

(72) Inventors: Hyun Eok SHIN, Yongin-si (KR); Sung Joo KWON, Yongin-si (KR); Ju Hyun LEE, Yongin-si (KR)

(21) Appl. No.: 18/884,111

(22) Filed: Sep. 13, 2024

(30) Foreign Application Priority Data
Oct. 24, 2023 (KR) 10-2023-0143212

(51) Int. Cl. H10K 59/80; G02B 27/01; H10K 59/12; H10K 71/60; H10K 102/10

(52) U.S. Cl. CPC H10K 59/878; G02B 27/0172; H10K 59/1201; H10K 71/60; H10K 2102/101

(57) ABSTRACT

The display device includes: a base layer including a groove surrounded by a protrusion which is disposed in a boundary area between sub-pixels, a reflective electrode of a display device is disposed on the base layer in the groove, a planarization pattern is disposed on the reflective electrode in the groove, an anode electrode is disposed the planarization pattern and contacting the reflective electrode, and a light emitting layer is disposed on the anode.

### CROSS-REFERENCE TO RELATED APPLICATION(S)

This application claims priority under 35 U.S.C. § 119 to Korean Patent Application No. 10-2023-0143212, filed on Oct. 24, 2023, in the Korean Intellectual Property Office, the disclosure of which is incorporated herein by reference in its entirety herein.

### BACKGROUND

### 1. Field

The present disclosure relates to a display device, a wearable electronic device, and a method of manufacturing the display device.

### 2. Description of the Related Art

An organic light emitting diode (OLED) is an active light emitting display device that has an advantage of not only having a wide viewing angle and excellent contrast, but also being able to be driven at a low voltage, being lightweight and thin, and having a fast response speed.

### SUMMARY

Embodiments may provide a display device with improved light output efficiency, a wearable electronic device, and a method of manufacturing the display device.

According to embodiments of the disclosure, a display device includes a base layer including a groove surrounded by a protrusion which is disposed in a boundary area between sub-pixels, a reflective electrode disposed on the base layer in the groove, a planarization pattern disposed on the reflective electrode in the groove, an anode electrode disposed on the planarization pattern and contacting the reflective electrode, and a light emitting layer disposed on the anode.

A portion of the reflective electrode may cover a side surface of the protrusion, and an upper surface of the portion of the reflective electrode, an upper surface of the planarization pattern, and an upper surface of the protrusion may be positioned on the same plane.

The upper surface of the portion of the reflective electrode, the upper surface of the planarization pattern, and the upper surface of the protrusion may be formed simultaneously through a polishing process.

The anode electrode may be directly disposed on the portion of the reflective electrode and the planarization pattern, and may directly contact the portion of the reflective electrode.

The reflective electrode may include a first layer, a second layer, and a third layer sequentially stacked, each of the first layer and the third layer may include a transparent conductive material, and the second layer may include a metal material.

The second layer may include silver.

The anode electrode may directly contact the second layer of the reflective electrode.

The light emitting layer may directly contact the base layer in a boundary area between the sub-pixels.

The planarization pattern may include an inorganic material, and the anode electrode may include a transparent conductive material.

The reflective electrode may surround the planarization pattern in a plan view, and the anode electrode may cover the reflective electrode.

The display device may further include a buffer pattern disposed under the reflective electrode in the groove.

The display device may further include a pixel defining layer disposed on the base layer in the boundary area between the sub-pixels, and a protrusion pattern disposed on the pixel defining layer and having a width that becomes wider toward an upper portion.

The display device may further include trenches formed in the base layer in the boundary area, and the trenches may be separated from each other.

According to embodiments of the disclosure, a wearable display device includes a display panel that emits light, and at least one lens disposed on the display panel. The display panel includes a base layer including a groove surrounded by a protrusion which is disposed in a boundary area between sub-pixels, a reflective electrode disposed on the base layer in the groove, a planarization pattern disposed on the reflective electrode in the groove, an anode electrode disposed the planarization pattern and contacting the reflective electrode, and a light emitting layer disposed on the anode electrode.

According to embodiments of the disclosure, a method of manufacturing a display device includes forming a groove in a base layer, the groove being surrounded by a protrusion which is disposed in a boundary area between sub-pixels, forming a reflective electrode layer on the base layer, forming a planarization layer on the reflective electrode layer, removing a portion of the reflective electrode layer and a portion of the planarization layer on the protrusion through a polishing process, forming an anode electrode on the base layer and the planarization layer, and forming a light emitting layer on the anode electrode.

The forming the groove in the base layer may include simultaneously forming the groove and a via hole in the base layer in the base layer using a half tone mask.

The forming the groove in the base layer may include forming the base layer, and forming the groove in the base layer.

The reflective electrode layer may be separated in the boundary area between the sub-pixels by the polishing process to form a reflective electrode which is disposed in the groove.

The forming the reflective electrode layer may include sequentially forming a first layer, a second layer, and a third layer on the base layer, each of the first layer and the third layer may include a transparent conductive material, and the second layer may include a metal material.

The second layer may include silver.

Specific details of other embodiments are included in the detailed description and drawings.

In the display device and the wearable electronic device according to embodiments of the disclosure, the reflective electrode may be disposed or buried in the groove of the base layer (or a via layer), and may be formed through a polishing process rather than a dry etching process. In this case, the reflective electrode may include silver, which has a reflectance higher than that of aluminum, and light output efficiency of the sub-pixel may be improved.

In addition, the planarization pattern may be disposed on the reflective electrode in the groove of the base layer, thereby preventing damage (for example, a scratch) to the reflective electrode during a CMP process.

The method of manufacturing the display device according to embodiments of the disclosure may form the reflective electrode disposed or buried in the groove of the base through the polishing process.

### BRIEF DESCRIPTION OF THE DRAWINGS

The above and other features of embodiments of the present disclosure will become more apparent by describing in further detail non-limiting embodiments thereof with reference to the accompanying drawings, in which:

FIG. 1 is a block diagram illustrating an embodiment of a display device;

FIG. 2 is a block diagram illustrating an embodiment of any one of sub-pixels of FIG. 1;

FIG. 3 is a circuit diagram illustrating an embodiment of the sub-pixel of FIG. 2;

FIG. 4 is a plan view illustrating an embodiment of a display panel of FIG. 1;

FIG. 5 is an exploded perspective view illustrating a portion of the display panel of FIG. 4;

FIG. 6 is a plan view illustrating an embodiment of any one of pixels of FIG. 5;

FIG. 7 is a cross-sectional view illustrating an embodiment of a pixel taken along a line I-I′ of FIG. 6;

FIG. 8 is a cross-sectional view illustrating an embodiment of a light emitting element layer included in any one of first to third sub-pixels of FIG. 7;

FIG. 9 is a plan view illustrating an embodiment of the light emitting element layer of FIG. 8;

FIG. 10 is a cross-sectional view illustrating a comparative example of the pixel taken along the line I-I′ of FIG. 6;

FIG. 11 is a cross-sectional view illustrating a comparative example of the light emitting element layer included in any one of the first to third sub-pixels of FIG. 7;

FIGS. 12A, 12B, 12C, 12D, and 12E are cross-sectional views illustrating a method of manufacturing a display device according to embodiments;

FIGS. 12F and 12G are cross-sectional views illustrating a method of forming a via layer of FIG. 12A;

FIG. 13 is a cross-sectional view illustrating an embodiment of the pixel taken along the line I-I′ of FIG. 6;

FIG. 14 is a cross-sectional view illustrating an embodiment of the pixel taken along the line I-I′ of FIG. 6;

FIG. 15 is a cross-sectional view illustrating an embodiment of a light emitting structure included in any one of first to third light emitting elements of FIG. 7;

FIG. 16 is a cross-sectional view illustrating an embodiment of the light emitting structure included in any one of the first to third light emitting elements of FIG. 7;

FIG. 17 is a plan view illustrating an embodiment of any one of the pixels of FIG. 5;

FIG. 18 is a plan view illustrating an embodiment of any one of the pixels of FIG. 5;

FIG. 19 is a block diagram illustrating an embodiment of a display system;

FIG. 20 is a perspective view illustrating an application example of the display system of FIG. 19; and

FIG. 21 is a diagram illustrating a head-mounted display device worn by a user of FIG. 20.

### DETAILED DESCRIPTION OF THE EMBODIMENT

Hereinafter, a preferred embodiment according to the disclosure is described in more detail with reference to the accompanying drawings. It should be noted that in the following description, only portions necessary for understanding an operation according to the disclosure are described, and descriptions of other portions are omitted in order not to obscure the subject matter of the disclosure. In some embodiments, the disclosure may be embodied in other forms without being limited to the embodiment described herein. However, the embodiment described herein is provided to describe in more detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Like reference numerals refer to like elements throughout, and duplicative descriptions thereof may not be provided. In some embodiments, in the drawings, the thicknesses, ratios, and dimensions of elements are exaggerated for effective description of the technical contents. As utilized herein, the term “and/or” includes any and all combinations that the associated configurations can define.

Terms utilized herein are for describing specific embodiments and are not intended to limit the disclosure. Throughout the specification, in a case where a certain portion “includes”, the case refers to that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations. The terms of a singular form include plural forms unless otherwise specified. For example, “a,” “an,” and “the” are intended to include the plural forms as well, unless the context clearly indicates otherwise.

As utilized herein, the terms “use,” “using,” and “used” may be considered synonymous with the terms “utilize,” “utilizing,” and “utilized,” respectively. As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” includes all combinations of one or more of the associated listed elements.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be provided above the other part, or provided under the other part as well. It will be understood that the terms “include” “includes,” “including,” “comprise,” “comprises”, “comprising,” “has,” “having,” and/or “have”, when utilized in this specification, specify the presence of stated features, integers, steps, operations, elements, components and/or groups thereof, but do not preclude the presence or addition of one or more other features, integers, steps, operations, elements, components, and/or groups thereof.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’” “exclude a or any ‘component’”, “‘component’-free”, and/or the like refers to that the “component” not being added, selected or utilized as a component in the composition, but the “component” of less than a suitable amount may still be included due to other impurities and/or external factor.

Here, terms such as first and second may be utilized to describe one or more suitable components, but these components are not limited to these terms. These terms are utilized to distinguish one component from another component. Therefore, a first component may refer to a second component within a range without departing from the scope disclosed herein.

Spatially relative terms such as “under”, “on”, and/or the like may be utilized for descriptive purposes, thereby describing a relationship between one element or feature and another element(s) or feature(s) as shown in the drawings. Spatially relative terms are intended to include other directions in utilize, in operation, and/or in manufacturing, in addition to the direction depicted in the drawings. For example, if (e.g., when) a device shown in the drawing is turned upside down, elements depicted as being positioned “under” other elements or features are positioned in a direction “on” the other elements or features. Therefore, in some embodiments, the term “under” may include both (e.g., simultaneously) directions of on and under. In some embodiments, the device may face in other directions (for example, rotated 90 degrees or in other directions) and thus the spatially relative terms utilized herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described herein, the shapes shown in the drawings may not show actual shapes of areas of a device, and the present embodiments are not limited thereto.

Hereinafter, embodiments of the disclosure will be described in more detail with reference to the accompanying drawings.

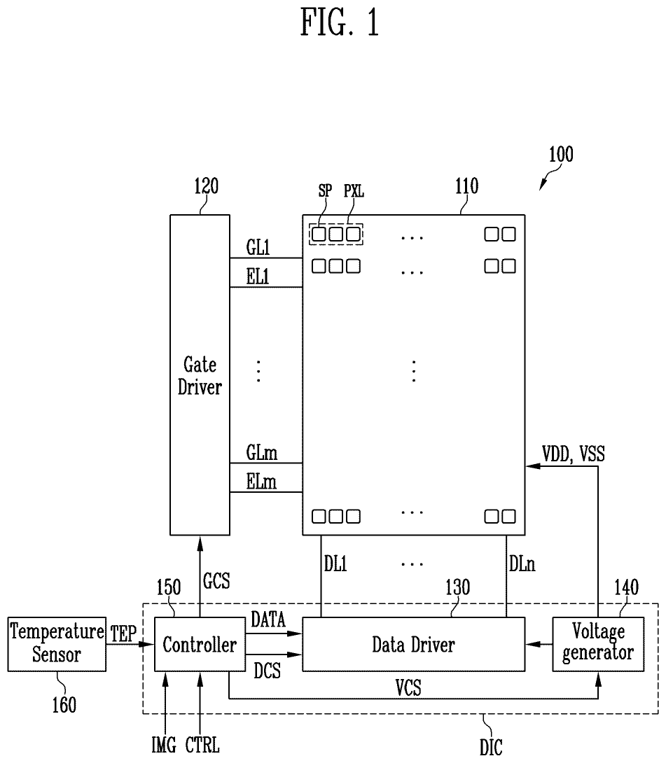

FIG. 1 is a diagram illustrating an embodiment of a display device.

Referring to FIG. 1, the display device 100 may include a display panel 110 (or a display unit), a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color such as red, green, blue, cyan, magenta, or yellow. Two or more sub-pixels among the sub-pixels SP may constitute one pixel PXL. For example, as shown in FIG. 1, three sub-pixels may constitute one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting the gate signals in synchronization with a timing at which data signals are applied, and the like.

In embodiments, first to m-th emission control lines EL1 to ELm connected to the sub-pixels SP of the row direction may be further provided. In this case, the gate driver 120 may include an emission control driver configured to control the first to m-th emission control lines EL1 to ELm, and the emission control driver may operate under control of the controller 150.

The gate driver 120 may be disposed on one side of the display panel 110. However, embodiments are not limited thereto. For example, the gate driver 120 may include two or more physically and/or logically divided drivers, and such drivers may be disposed on one side of the display panel 110 and another side of the display panel 110 opposite the one side. As described above, the gate driver 120 may be disposed around the display panel 110 in various shapes according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the data lines DL1 to DLm. Accordingly, the corresponding sub-pixels SP may generate light corresponding to the data signals. Accordingly, an image is displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device 100. For example, the voltage generator 140 may be configured to generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a predetermined reference voltage may be applied to the first to n-th data lines DL1 to DLn, and the voltage generator 140 may generate such a reference voltage.

The controller 150 controls overall operations of the display device 100. The controller 150 receives input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. In embodiments, the controller 150 may output the image data DATA after rearranging the input image data IMG to be suitable for the sub-pixels SP of a row unit.

Two or more components of the data driver 130, the voltage generator 140, and the controller 150 may be embedded into one integrated circuit. As shown in FIG. 1, the data driver 130, the voltage generator 140, and the controller 150 may be embedded into a driver integrated circuit DIC. In this case, the data driver 130, the voltage generator 140, and the controller 150 may be functionally divided components in one driver integrated circuit DIC. In other embodiments, at least one of the data driver 130, the voltage generator 140, and the controller 150 may be provided as a component separated from the driver integrated circuit DIC.

The display device 100 may include at least one temperature sensor 160. The temperature sensor 160 is configured to sense a temperature around the temperature sensor 160 and generate temperature data TEP indicating the sensed temperature. In embodiments, the temperature sensor 160 may be disposed adjacent to the display panel 110 and/or the driver integrated circuit DIC.

The controller 150 may control various operations of the display device 100 according to the temperature data TEP. In embodiments, the controller 150 may adjust a luminance of the image output from the display panel 110 according to the temperature data TEP. For example, the controller 150 may control the data signals and the first and second power voltages VDD and VSS by controlling components such as the data driver 130 and/or the voltage generator 140.

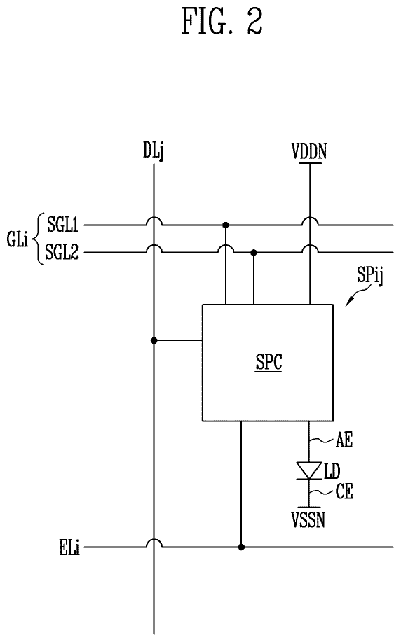

FIG. 2 is a block diagram illustrating an example of any one of the sub-pixels of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD is connected between a first power voltage node VDDN and a second power voltage node VSSN. The first power voltage node VDDN is a node that transfers the first power voltage VDD of FIG. 1, and the second power voltage node VSSN is a node that transfers the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light emitting element LD according to signals received through such signal lines.

The sub-pixel circuit SPC may operate in response to a gate signal received through the i-th gate line GLi. The i-th gate line GLi may include one or more sub-gate lines. In embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described above, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. When the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. The sub-pixel circuit SPC may adjust a current flowing from the first power voltage node VDDN to the second power voltage node VSSN through the light emitting element LD according to the stored voltage in response to the emission control signal received through the i-th emission control line ELi. Accordingly, the light emitting element LD may generate light of a luminance corresponding to the data signal.

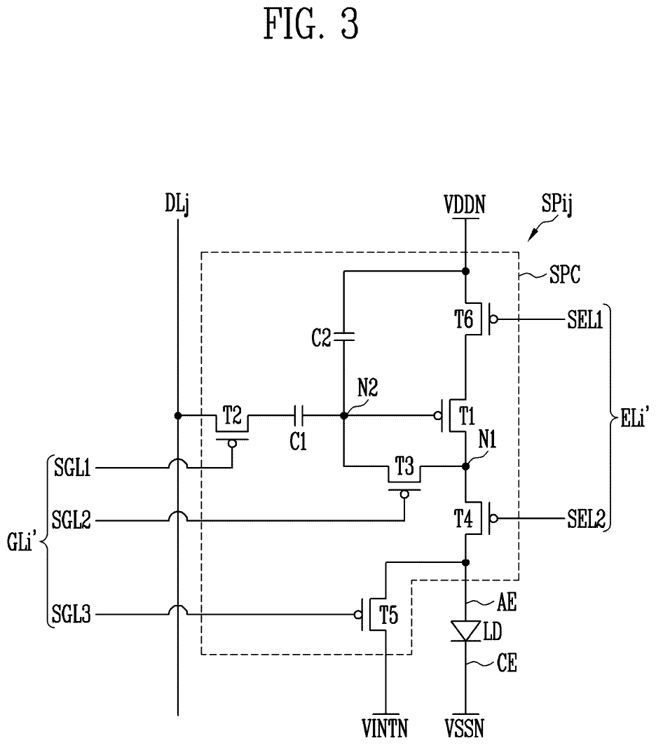

FIG. 3 is a circuit diagram illustrating an embodiment of the sub-pixel of FIG. 2.

Referring to FIG. 3, the sub-pixel SPij may include a sub-pixel circuit SPC and a light emitting element LD.

The sub-pixel circuit SPC may be connected to an i-th gate line GLi′, an i-th emission control line ELi′, and the j-th data line DLj. Compared to the i-th gate line GLi of FIG. 2, the i-th gate line GLi′ may further include a third sub-gate line SGL3. Compared to the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 is connected between a first power voltage node VDDN and a first node N1. A gate of the first transistor T1 may be connected to a second node N2, and thus the first transistor T1 may be turned on according to a voltage level of the second node N2. The first transistor T1 may be referred to as a driving transistor.

The second transistor T2 is connected between the j-th data line DLj and the second node N2. A gate of the second transistor T2 may be connected to the first sub-gate line SGL1, and thus the second transistor T2 may be turned on in response to a gate signal of the first sub-gate line SGL1. The second transistor T2 may be referred to as a switching transistor.

The third transistor T3 is connected between the first node N1 and the second node N2. A gate of the third transistor T3 may be connected to the second sub-gate line SGL2, and thus the third transistor T3 may be turned on in response to a gate signal of the second sub-gate line SGL2.

The fourth transistor T4 is connected between the first node N1 and the anode electrode AE of the light emitting element LD. A gate of the fourth transistor T4 may be connected to the second sub-emission control line SEL2, and thus the fourth transistor T4 may be turned on in response to an emission control signal of the second sub-emission control line SEL2.

The fifth transistor T5 is connected between the anode electrode AE of the light emitting element LD and an initialization voltage node VINTN. The initialization voltage node VINTN is configured to transfer an initialization voltage. In embodiments, the initialization voltage may be provided by voltage generator 140 of FIG. 1. In other embodiments, the initialization voltage may be provided by an external device of the display device 100. A gate of the fifth transistor T5 may be connected to the third sub-gate line SGL3, and thus the fifth transistor T5 may be turned on in response to a gate signal of the third sub-gate line SGL3.

The sixth transistor T6 is connected between the first power voltage node VDDN and the first transistor T1. A gate of the sixth transistor T6 may be connected to the first sub-emission control line SEL1, and thus the sixth transistor T6 may be turned on in response to an emission control signal of the first sub-emission control line SEL1.

The first capacitor C1 is connected between the second transistor T2 and the second node N2. The second capacitor C2 is connected between the first power voltage node VDDN and the second node N2.

As described above, the sub-pixel circuit SPC may include the first to sixth transistors T1 to T6, and the first and second capacitors C1 and C2. However, embodiments are not limited thereto. The sub-pixel circuit SPC may be implemented as any one of various types of circuits including a plurality of transistors and one or more capacitors. For example, the sub-pixel circuit SPC may include two transistors and one capacitor. According to embodiments of the sub-pixel circuit SPC, the number of sub-gate lines included in the i-th gate line GLi′ and the number of sub-emission control lines included in the i-th emission control line ELi′ may be altered.

The first to sixth transistors T1 to T6 may be P-type transistors. Each of the first to sixth transistors T1 to T6 may be a metal oxide silicon field effect transistor (MOSFET). However, embodiments are not limited thereto. For example, at least one of the first to sixth transistors T1 to T6 may be replaced with an N-type transistor.

In embodiments, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode electrode AE, the cathode electrode CE, and the light emitting layer. The light emitting layer may be disposed between the anode electrode AE and the cathode electrode CE. After the data signal transferred through the j-th data line DLj is stored in the second capacitor C2, when the emission control signals of the first and second sub-emission control lines SEL1 and SEL2 are enabled to a low level, the fourth and sixth transistors T4 and T6 may be turned on. In addition, the first transistor T1 may be turned on according to the voltage stored the second capacitor C2, and thus a current may flow from the first power voltage node VDDN to the second power voltage node VSSN. The light emitting element LD may emit light according to an amount of the flowing current.

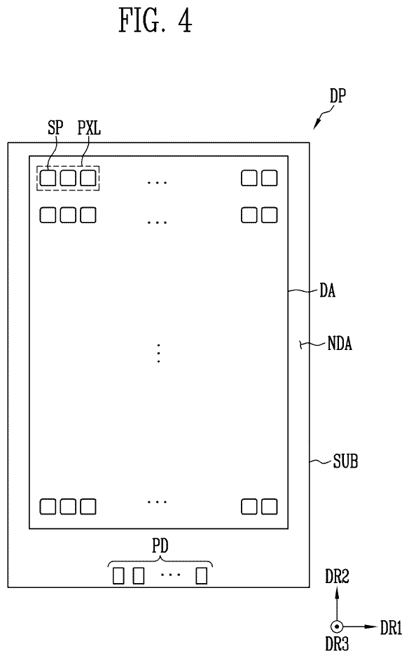

FIG. 4 is a plan view illustrating an embodiment of the display panel of FIG. 1.

Referring to FIG. 4, the display panel DP may include a display area DA and a non-display area NDA. The display panel DP displays an image through the display area DA. The non-display area NDA is disposed around the display area DA.

The display panel DP may include a substrate SUB, the sub-pixels SP, and pads PD.

When the display panel DP is used as a display screen of a head mounted display (HMD) device, a virtual reality (VR) device, a mixed reality (MR) device, an augmented reality (AR) device, or the like, the display panel DP may be positioned very close to user's eyes. In this case, sub-pixels SP of a relatively high integration degree are required. In order to increase an integration degree of the sub-pixels SP, the substrate SUB may be provided as a silicon substrate. The sub-pixels SP and/or the display panel DP may be formed on the substrate SUB, which is the silicon substrate. The display device 100 (refer to FIG. 1) including the display panel DP formed on the silicon substrate SUB may be referred to as an OLED on silicon (OLEDoS) display device.

The sub-pixels SP are disposed in the display area DA on the substrate SUB. The sub-pixels SP may be arranged in a matrix shape along a first direction DR1 and a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILE™ shape. The first direction DR1 may be a row direction, and the second direction DR2 may be a column direction.

Two or more sub-pixels among the plurality of sub-pixels SP may constitute one pixel PXL.

A component for controlling the sub-pixels SP may be disposed in the non-display area NDA on the substrate SUB. For example, lines connected to the sub-pixels SP, such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be formed on the display panel DP in the non-display area NDA. In other embodiments, the gate driver 120 may be implemented as an integrated circuit separated from the display panel DP. In embodiments, the temperature sensor 160 may be disposed in the non-display area NDA to sense a temperature of the display panel DP.

The pads PD are disposed in the non-display area NDA on the substrate SUB. The pads PD may be electrically connected to the sub-pixels SP through signal lines. For example, the pads PD may be connected to the sub-pixels SP through the first to n-th data lines DL1 to DLn.

The display panel DP and other components of the display device 100 (refer to FIG. 1) may be connected to each other through the pads PD. In embodiments, voltages and signals necessary for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In embodiments, a circuit board may be electrically connected to the pads PD using a conductive adhesive member such as an anisotropic conductive film. The circuit board may be a flexible circuit board (FPCB) or a flexible film having a flexible material. The driver integrated circuit DIC may be mounted on the circuit board to be electrically connected to the pads PD.

In embodiments, the display area DA may have various shapes. The display area DA may have various shapes which include straight and/or curved sides. For example, the display area DA may have shapes such as a polygon, a circle, a semicircle, and an ellipse.

In embodiments, the display panel DP may have a flat display surface. In other embodiments, the display panel DP may have a display surface that is at least partially rounded. In embodiments, the display panel DP may be bendable, foldable, or rollable. In these cases, the display panel DP and/or the substrate SUB may include materials having a flexible property.

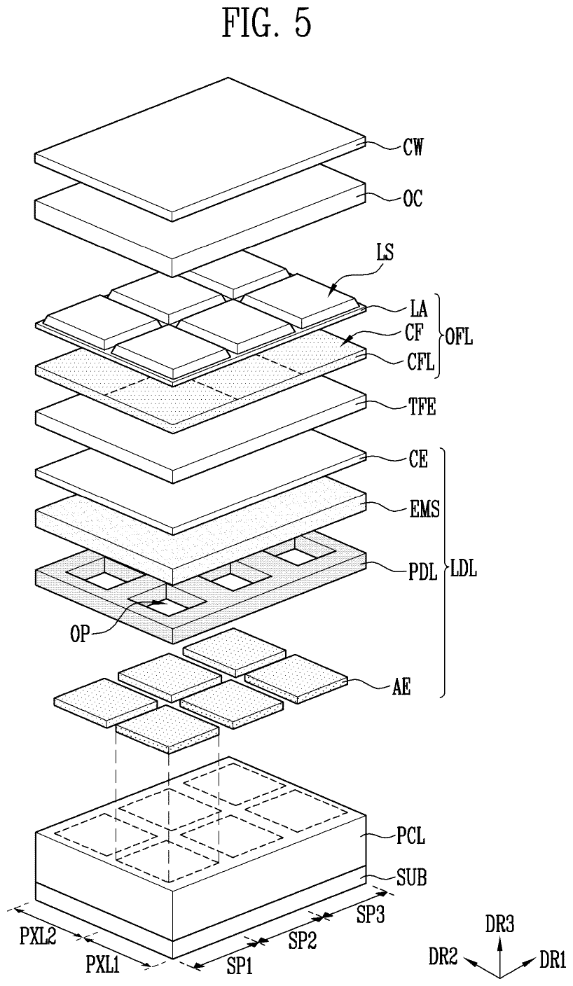

FIG. 5 is an exploded perspective view illustrating a portion of the display panel of FIG. 4. In FIG. 5, for clear and concise description, a portion of the display panel DP corresponding to two pixels PXL1 and PXL2 among the pixels PXL of FIG. 4 is schematically shown. A portion of the display panel DP corresponding to remaining pixels may be similarly configured.

Referring to FIGS. 4 and 5, each of the first and second pixels PXL1 and PXL2 may include first to third sub-pixels SP1, SP2, and SP3. However, embodiments are not limited thereto. For example, each of the first and second pixels PXL1 and PXL2 may include four sub-pixels or two sub-pixels.

In FIG. 5, the first to third sub-pixels SP1, SP2, and SP3 have quadrangle shapes when viewed from a third direction DR3 crossing the first and second directions DR1 and DR2, and have sizes equal to each other. However, embodiments are not limited thereto. The first to third sub-pixels SP1, SP2, and SP3 may be modified to have various shapes.

The display panel DP may include the substrate SUB, a pixel circuit layer PCL, a light emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In still other embodiments, the substrate SUB may include a polyimide (PI) substrate.

The pixel circuit layer PCL is disposed on the substrate SUB. The substrate SUB and/or the pixel circuit layer PCL may include insulating layers and conductive patterns disposed between the insulating layers. The conductive patterns of the pixel circuit layer PCL may function as at least a portion of circuit elements, signal lines, and the like. The conductive patterns may include copper, but embodiments are not limited thereto.

The circuit elements may include the sub-pixel circuit SPC (refer to FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. In embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The signal lines of the pixel circuit layer PCL may be connected to each of the first to third sub-pixels SP1, SP2, and SP3. The signal lines may include a gate line, an emission control line, a data line, and the like. The signal lines may further include a line connected to the first power voltage node VDDN of FIG. 2. In addition, the signal lines may further include a line connected to the second power voltage node VSSN of FIG. 2.

The light emitting element layer LDL may include the anode electrode AE, a light emitting structure EMS, and the cathode electrode CE. According to an embodiment, the light emitting element layer LDL may not include a pixel defining layer PDL. In other words, the pixel defining layer PDL may be omitted.

The anode electrode AE may be disposed on the pixel circuit layer PCL. The anode electrode AE may be connected to the circuit elements of the pixel circuit layer PCL. The anode electrode AE may include an opaque conductive material capable of reflecting light, but embodiments are not limited thereto.

The pixel defining layer PDL may be disposed on the anode electrode AE. The pixel defining layer PDL may include an opening OP exposing a portion of each of the anode electrode AE. The openings OP of the pixel defining layer PDL may be emission areas corresponding to the first to third sub-pixels SP1 to SP3, respectively.

In embodiments, the pixel defining layer PDL may include an inorganic material. In this case, the pixel defining layer PDL may include a plurality of stacked inorganic layers. For example, the pixel defining layer PDL may include silicon oxide SiOₓ and silicon nitride SiNₓ. In other embodiments, the pixel defining layer PDL may include an organic material. However, a material of the pixel defining layer PDL is not limited thereto.

The light emitting structure EMS may be disposed on the anode electrode AE exposed by the opening OP of the pixel defining layer PDL. The light emitting structure EMS may include a light emitting layer configured to generate light, an electron transport layer configured to transport an electron, a hole transport layer configured to transport a hole, and the like.

In embodiments, the light emitting structure EMS may fill the opening OP of the pixel defining layer PDL, and may be entirely disposed on the pixel defining layer PDL. In other words, the light emitting structure EMS may extend across the first to third sub-pixels SP1 to SP3. In this case, at least a portion of layers in the light emitting structure EMS may be disconnected or bent at boundaries between the first to third sub-pixels SP1 to SP3. However, embodiments are not limited thereto. For example, portions of the light emitting structure EMS corresponding to the first to third sub-pixels SP1 to SP3 may be separated from each other, and each of the portions may be disposed in the opening OP of the pixel defining layer PDL.

The cathode electrode CE may be disposed on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin thickness. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), and a mixture thereof. However, a material of the cathode electrode CE is not limited thereto.

It may be understood that one of the anode electrode AE, a portion of the light emitting structure EMS overlapping the one of the anode electrode AE, and a portion of the cathode electrode CE overlapping the one of the anode electrode AE may constitute one light emitting element LD (refer to FIG. 2). In other words, each of the light emitting elements of the first to third sub-pixels SP1 to SP3 may include one anode electrode, a portion of the light emitting structure EMS overlapping the one anode electrode AE, and a portion of the cathode electrode CE overlapping the one anode electrode AE. In each of the first to third sub-pixels SP1 to SP3, holes injected from the anode electrode AE and electrons injected from the cathode electrode CE may be transported into the light emitting layer of the light emitting structure EMS to form excitons, and when the excitons transits from an excited state to a ground state, light may be generated. A luminance of light may be determined according to an amount of a current flowing through the light emitting layer. According to a configuration of the light emitting layer, a wavelength range of the generated light may be determined.

The encapsulation layer TFE is disposed on the cathode electrode CE. The encapsulation layer TFE may cover the light emitting element layer LDL and/or the pixel circuit layer PCL. The encapsulation layer TFE may be configured to prevent oxygen, moisture, and/or the like from permeating to the light emitting element layer LDL. In embodiments, the encapsulation layer TFE may include a structure in which one or more inorganic layers and one or more organic layers are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenol resin, polyamides resin, polyimide resin, unsaturated polyester resin, polyphenylenether resin, polyphenylenesulfide resin, or benzocyclobutene (BCB). However, materials of the organic and the inorganic layers of the encapsulation layer TFE are not limited thereto.

In order to improve an encapsulation efficiency of the encapsulation layer TFE, the encapsulation layer TFE may further include a thin film including aluminum oxide (AlOₓ). The thin film including the aluminum oxide may be positioned on an upper surface of the encapsulation layer TFE facing the optical functional layer OFL and/or a lower surface of the encapsulating layer TFE facing the light emitting element layer LDL.

The thin film including the aluminum oxide may be formed through atomic layer deposition (ALD) method. However, embodiments are not limited thereto. The encapsulation layer TFE may further include a thin film formed of at least one of various materials suitable for improving the encapsulation efficiency.

The optical functional layer OFL is disposed on the encapsulation layer TFE. The optical functional layer OFL may include a color filter layer CFL and a lens array LA.

The color filter layer CFL is disposed between the encapsulation layer TFE and the lens array LA. The color filter layer CFL is configured to filter the light emitted from the light emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light emitting structure EMS of each sub-pixel, at least a portion of the color filters CF may be omitted.

The lens array LA is disposed on the color filter layer CFL. The lens array LA may include lenses LS respectively corresponding to the first to third sub-pixels SP1 to SP3. Each of the lenses LS may improve light output efficiency by redirecting the light emitted from the light emitting structure EMS to an intended path. The lens array LA may have a relatively high refractive index. For example, the lens array LA may have a refractive index higher than that of the overcoat layer OC. In embodiments, the lenses LS may include an organic material. In embodiments, the lenses LS may include an acrylic material. However, a material of the lenses LS is not limited thereto.

In embodiments, compared to the opening OP of the pixel defining layer PDL, at least a portion of the color filters CF of the color filter layer CFL and at least a portion of the lenses LS of the lens array LA may be shifted in a direction parallel to the plane defined by the first and second directions DR1 and DR2. Specifically, in a central area of the display area DA, a center of the color filter and a center of the lens may be aligned with or overlap with a center of the opening OP of the corresponding pixel definition layer PDL when viewed in the third direction DR3. For example, in the central area of the display area DA, the opening OP of the pixel defining layer PDL may be aligned with the corresponding color filter of the color filter layer CFL and the corresponding lens of the lens array LA. In an area adjacent to the non-display area NDA in the display area DA, the center of the color filter and the center of the lens may be shifted in a plane direction from the center of the opening OP of the corresponding pixel defining layer PDL when viewed in the third direction DR3. For example, in the area adjacent to the non-display area NDA in the display area DA, the opening OP of the pixel defining layer PDL may be misaligned with the corresponding color filter of the color filter layer CFL and the corresponding lens of the lens array LA. Accordingly, at a center of the display area DA, the light emitted from the light emitting structure EMS may be efficiently output in a normal direction of a display surface. In the area adjacent to the non-display area NDA in the display area DA, the light emitted from the light emitting structure EMS may be efficiently output in a direction inclined by a predetermined angle with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than that of the lens array LA.

The cover window CW may be disposed on the overcoat layer OC. The cover window CW is configured to protect layers disposed thereunder. The cover window CW may have a refractive index higher than that of the overcoat layer OC. The cover window CW may include glass, but embodiments are not limited thereto. For example, the cover window CW may be an encapsulation glass configured to protect components disposed thereunder. In other embodiments, the cover window CW may be omitted.

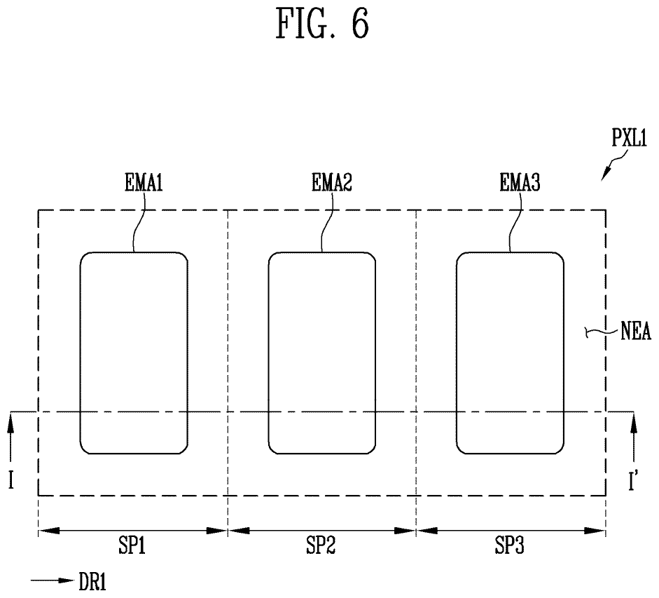

FIG. 6 is a plan view illustrating an embodiment of any one of the pixels of FIG. 5. In FIG. 6, the first pixel PXL1 among the first and second pixels PXL1 and PXL2 of FIG. 5 is schematically shown for clear and concise description. The remaining pixels may be configured similarly to the first pixel PXL1.

Referring to FIGS. 5 and 6, the first pixel PXL1 may include the first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMA1 may be an area where light is emitted from a portion of the light emitting structure EMS (refer to FIG. 5) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3. As described with reference to FIG. 5, each emission area may be the opening OP of the pixel defining layer PDL corresponding to each of the first to third sub-pixels SP1 to SP3.

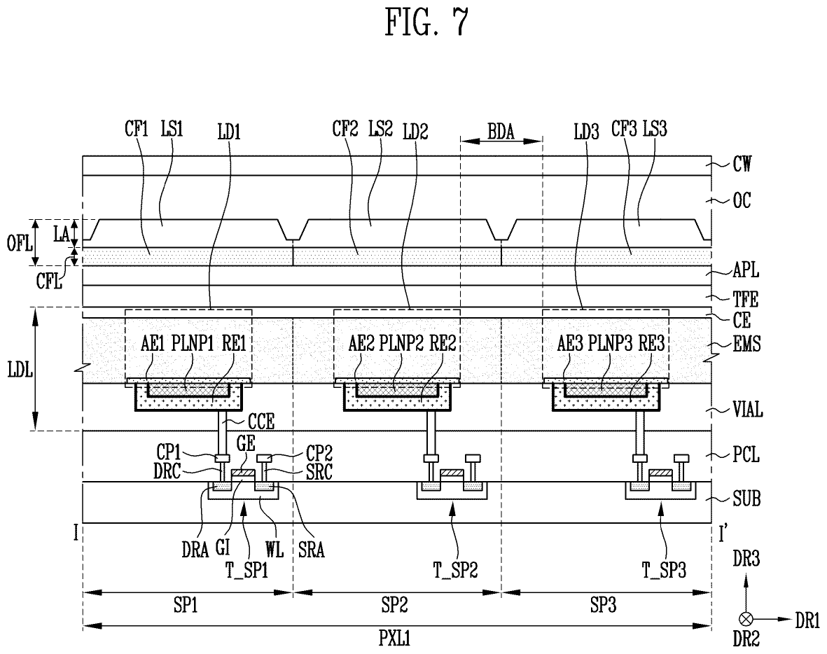

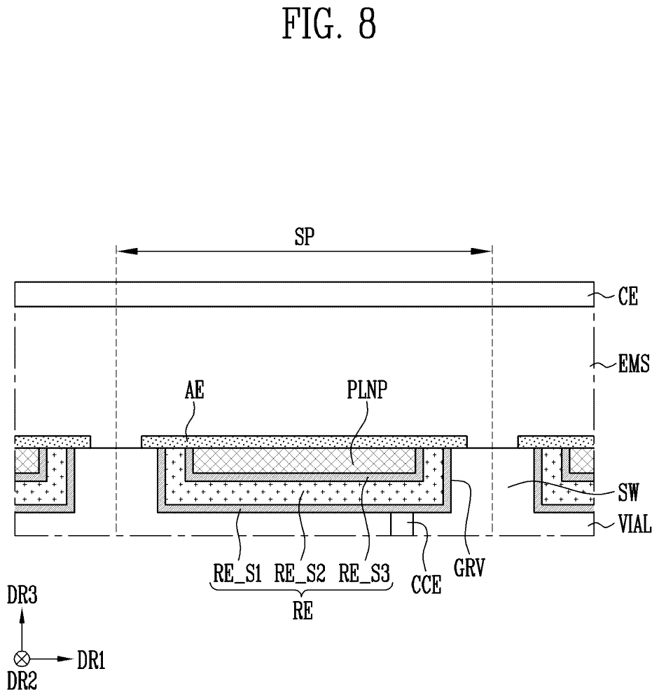

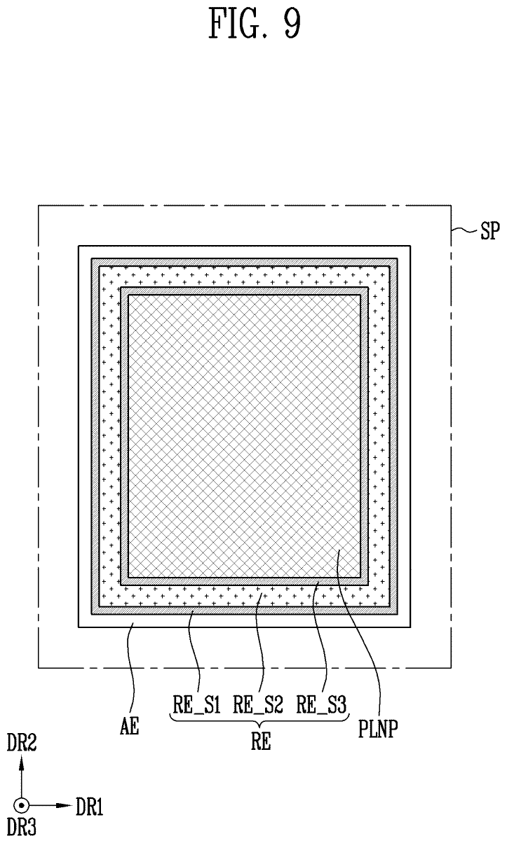

FIG. 7 is a cross-sectional view illustrating an embodiment of the pixel taken along a line I-I′ of FIG. 6. FIG. 8 is a cross-sectional view illustrating an embodiment of the light emitting element layer included in any one of the first to third sub-pixels of FIG. 7. FIG. 9 is a plan view illustrating an embodiment of the light emitting element layer of FIG. 8.

Referring to FIGS. 7 to 9, the pixel circuit layer PCL is disposed on the substrate SUB.

The substrate SUB may include a silicon wafer substrate formed using a semiconductor process. For example, the substrate SUB may include silicon, germanium, and/or silicon-germanium.

The pixel circuit layer PCL is disposed on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 2) of the first sub-pixel SP1, the transistor T_SP2 of the second sub-pixel SP2 may be any one of the transistors included in the sub-pixel circuit SPC of the second sub-pixel SP2, and the transistor T_SP3 of the third sub-pixel SP3 may be any one of the transistors included in the sub-pixel circuit SPC of the third sub-pixel SP3. In FIG. 7, for clear and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be disposed in the substrate SUB. A well WL formed through an ion injection process may be disposed in the substrate SUB, and the source area SRA and the drain area DRA may be disposed to be spaced apart from each other in the well WL. An area between the source area SRA and the drain area DRA in the well WL may be defined as a channel area.

The gate electrode GE may overlap the channel area between the source area SRA and the drain area DRA and may be disposed in the pixel circuit layer PCL. The gate electrode GE may be spaced apart from the well WL or the channel area with an insulating material such as a gate insulating layer GI disposed between the gate electrode GE and the channel area. The gate electrode GE may include a conductive material.

A plurality of layers included in the pixel circuit layer PCL may include insulating layers and conductive patterns disposed between the insulating layers, and such conductive patterns may include first and second conductive patterns CP1 and CP2. The first conductive pattern CP1 may be electrically connected to the drain area DRA through a drain connection portion DRC formed through one or more insulating layers. The second conductive pattern CP2 may be electrically connected to the source area SRA through a source connection portion SRC formed through one or more insulating layers.

As the gate electrode GE and the first and second conductive patterns CP1 and CP2 are connected to different circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include the circuit elements of each of the first to third sub-pixels SP1 to SP3.

The light emitting element layer LDL is disposed on the pixel circuit layer PCL. The light emitting element layer LDL may include a via layer VIAL, first to third reflective electrodes RE1 to RE3 (or a reflective electrode RE, refer to FIG. 8), first to third planarization patterns PLNP1 to PLNP3 (or a planarization pattern PLNP, refer to FIG. 8), first to third anode electrodes AE1 to AE3 (or the anode electrode AE, refer to FIG. 8), the light emitting structure EMS, and the cathode electrode CE.

The via layer VIAL (or a base layer) may cover the pixel circuit layer PCL. The via layer VIAL may include at least one of silicon oxide (SiOₓ), silicon nitride (SiNₓ), and silicon carbon nitride (SiCN), but embodiments are not limited thereto.

In embodiments, the via layer VIAL may include a groove (GRV) which is recessed from an upper surface of the via layer VIAL and surrounded by a protrusion SW of the via layer VIAL disposed in a boundary area BDA between the sub-pixels SP1 to SP3. For example, with reference to FIG. 9, the protrusion SW may be disposed to surround the reflective electrode RE.

The protrusion SW may be a portion of the via layer VIAL, but is not limited thereto. For example, the protrusion SW may be formed through a process different from that of the via layer VIAL or may be a separate component including a material different from that of the via layer VIAL. In this case, the groove GRV may be an area in which the material forming the protrusion SW is removed.

On the via layer VIAL, the first to third reflective electrodes RE1 to RE3 are disposed in the first to third sub-pixels SP1 to SP3, respectively. Each of the first to third reflective electrodes RE1 to RE3 may contact the circuit element (for example, the first conductive pattern CP1) disposed in the pixel circuit layer PCL through a connection electrode CCE formed through the via layer VIAL. Each of the first to third reflective electrodes RE1 to RE3 may directly contact the circuit element (for example, the first conductive pattern CP1) disposed in the pixel circuit layer PCL.

In an embodiment, each of the first to third reflective electrodes RE1 to RE3 may be disposed in the groove GRV of the via layer VIAL. As shown in FIG. 8, the reflective electrode RE may be disposed on a bottom surface of the groove GRV, and a portion of the reflective electrode RE may cover a side surface of the protrusion SW.

The first to third reflective electrodes RE1 to RE3 may function as a full mirror reflecting the light emitted from the light emitting structure EMS toward the display surface (or the cover window CW). The first to third reflective electrodes RE1 to RE3 may include metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them, but embodiments are not limited thereto.

In an embodiment, the reflective electrode RE may include a first layer RE_S1, a second layer RE_S2, and a third layer RE_S3 that are sequentially stacked.

As shown in FIG. 8, on the bottom surface of the groove GRV of the via layer VIAL, the first layer RE_S1, the second layer RE_S2, and the third layer RE_S3 may be sequentially stacked in the third direction DR3. When the reflective electrode RE covers a side surface of the protrusion SW of the via layer VIAL, the first layer RE_S1, the second layer RE_S2, and the third layer RE_S3 may be sequentially stacked in a direction perpendicular to the side surface of the protrusion SW (for example, in the first direction DR1) on the side surface of the protrusion SW. An end of the first layer RE_S1, an end of the second layer RE_S2, and an end of the third layer RE_S3 may be positioned in the same plane (for example, in the same plane as an upper surface of the protrusion SW).

In an embodiment, as shown in FIG. 9, in a plan view, the first layer RE_S1 may surround the second layer RE_S2, and the second layer RE_S2 may surround the third layer RE_S3.

In an embodiment, each of the first layer RE_S1 and the third layer RE_S3 may include a transparent conductive material, and the second layer RE_S2 may include a metal material. For example, each of the first layer RE_S1 and the third layer RE_S3 may include indium tin oxide, indium zinc oxide, indium tin zinc oxide, aluminum zinc oxide, gallium zinc oxide, zinc tin oxide, or gallium tin oxide. For example, the second layer RE_S2 may include silver (Ag).

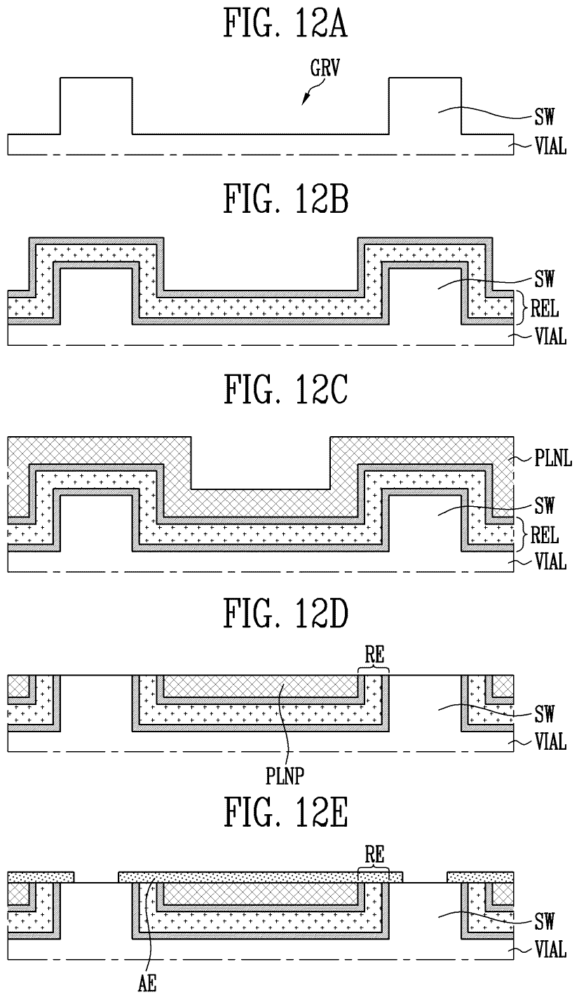

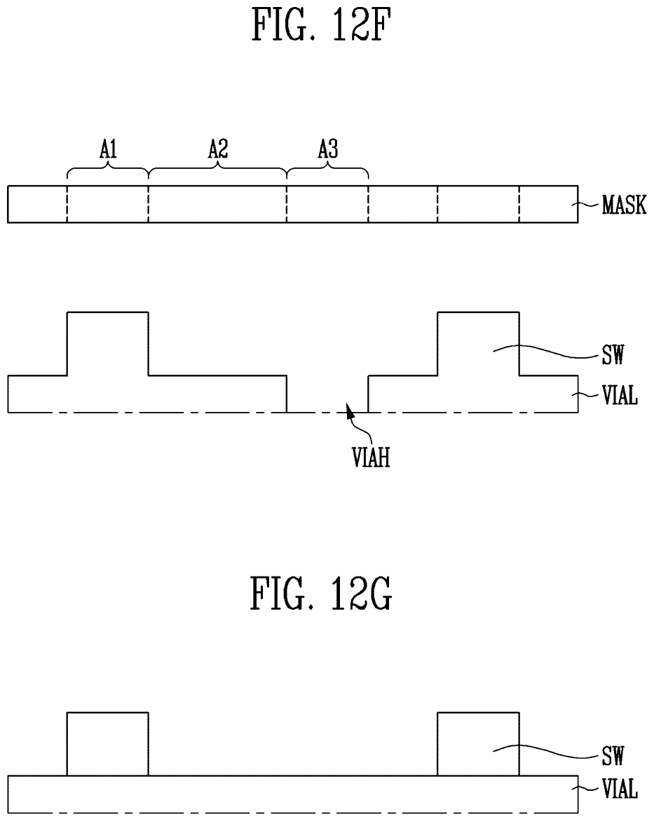

As will be described later with reference to FIG. 12C, the third layer RE_S3 may prevent damage to the second layer RE_S2 during a process of forming (or patterning) the reflective electrode RE.

The first to third planarization patterns PLNP1 to PLNP3 are disposed on the first to third reflective electrodes RE1 to RE3, respectively.

In an embodiment, each of the first to third planarization patterns PLNP1 to PLNP3 may be disposed in the groove of the via layer VIAL. The first to third planarization patterns PLNP1 to PLNP3 may have a flat surface. The first to third planarization patterns PLNP1 to PLNP3 may planarize step differences due to the groove GRV of the via layer VIAL (and the first to third reflective electrodes RE1 to RE3).

As will be described later with reference to FIG. 12C, the first to third planarization patterns PLNP1 to PLNP3 may prevent damage to the reflective electrodes RE1 to RE3 (in particular, the second layer RE_S2) in a process of separating (or patterning) the reflective electrodes RE1 to RE3 from each other.

In an embodiment, as shown in FIG. 9, the planarization pattern PLNP may be surrounded by the reflective electrode RE (or the third layer RE_S3).

The first to third planarization patterns PLNP1 to PLNP3 may include an insulating material. For example, the first to third planarization patterns PLNP1 to PLNP3 may include an inorganic material such as silicon oxide (SiOₓ) or silicon nitride (SiNₓ), but embodiments are not limited thereto.

In an embodiment, as shown in FIG. 8, an upper surface of the planarization pattern PLNP, an upper surface of the protrusion SW, and an end of the reflective electrode RE (or an upper surface of a portion of the reflective electrode RE covering the side surface of the protrusion SW) may be positioned in the same plane. As will be described later with reference to FIG. 12C, the upper surface of the planarization pattern PLNP, the upper surface of the protrusion SW, and the end of the reflective electrode RE may be formed simultaneously through a polishing process (chemical mechanical polishing (CMP).

On the via layer VIAL (or the protrusion SW) and the first to third planarization patterns PLNP1 to PLNP3, the first to third anode electrodes AE1 to AE3 respectively overlapping the first to third reflective electrodes RE1 to RE3 are disposed. The first to third anode electrodes AE1 to AE3 may have shapes similar to those of the first to third emission areas EMA1 to EMA3 of FIG. 6 when viewed in the third direction DR3. The first to third anode electrodes AE1 to AE3 are respectively connected to the first to third reflective electrodes RE1 to RE3.

In an embodiment, as shown in FIG. 8, the anode electrode AE may be directly disposed on the end of the reflective electrode RE and the planarization pattern PLNP, and may be directly connected to the end of the reflective electrode RE. When the reflective electrode RE includes the first layer RE_S1, the second layer RE_S2, and the third layer RE_S3, the anode electrode AE may be directly connected to ends of each of the first layer RE_S1, the second layer RE_S2, and the third layer RE_S3.

When the planarization pattern PLNP is disposed between the anode electrode AE and the reflection electrode RE, most of the anode electrode AE and the reflection electrode RE may be separated from each other by the planarization pattern PLNP. Accordingly, the anode electrode AE and the reflective electrode RE may have a separate structure rather than an integrated structure.

In an embodiment, as shown in FIG. 9, the anode electrode AE may cover the reflective electrode RE and the planarization pattern PLNP. The anode electrode AE may completely cover the reflective electrode RE and the planarization pattern PLNP in a plan view.

In embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO). However, a material of the first to third anode electrodes AE1 to AE3 is not limited thereto.

In an embodiment, as shown in FIG. 8, the anode electrode AE may completely cover the first layer RE_S1, the second layer RE_S2, and the third layer RE_S3 of the reflective electrode RE and the planarization pattern PLNP.

The light emitting structure EMS (or the light emitting layer) is disposed on the first to third anode electrodes AE1 to AE3. The light emitting structure EMS may emit light.

The light emitting structure EMS may be disposed entirely across the first to third sub-pixels SP1 to SP3. According to an embodiment, the light emitting structure EMS may be at least partially disconnected in the boundary area BDA. Accordingly, when the display panel DP is operated, a leakage current flowing from each of the first to third sub-pixels SP1 to SP3 to a sub-pixel neighboring thereto through layers included in the light emitting structure EMS may be reduced. Therefore, first to third light emitting elements LD1 to LD3 may operate with relatively high reliability.

In an embodiment, the light emitting structure EMS may be directly disposed on the via layer VIAL in the boundary area BDA disposed between the first to third sub-pixels SP1 to SP3.

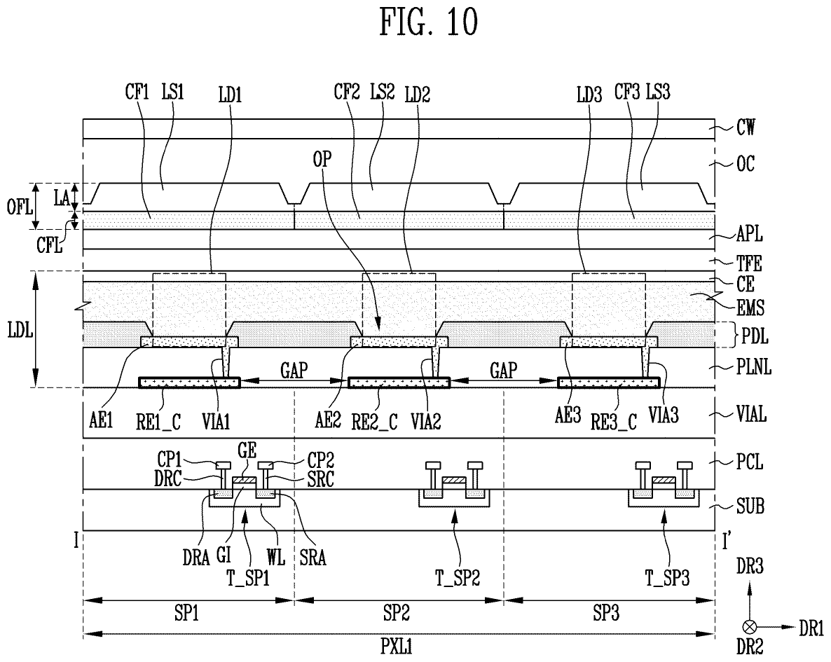

For reference, when the reflective electrode RE having a certain thickness is not buried in the via layer VIAL and is disposed on the via layer VIAL, and when the light emitting structure EMS is directly disposed on a side surface of the reflective electrode RE, the light emitting structure EMS on the side surface of the reflective electrode RE may emit light, or another problem may occur. In order to prevent light emission from the side surface of the reflective electrode RE or the like, the pixel defining layer PDL (refer to FIG. 10) may be disposed on the anode electrode AE and the via layer VIAL in the boundary area BDA. Meanwhile, since the reflective electrode RE according to embodiments is buried in the via layer VIAL, a separate pixel defining layer may not be required, and the light emitting structure EMS may be directly disposed on the via layer VIAL in the boundary area BDA.

The cathode electrode CE may be disposed on the light emitting structure EMS. The cathode electrode CE may be commonly provided to the first to third sub-pixels SP1 to SP3. The cathode electrode CE may function as a half mirror that partially transmits and partially reflects the light emitted from the light emitting structure EMS.

The first anode electrode AE1, a portion of the light emitting structure EMS overlapping the first anode electrode AE1, and a portion of the cathode electrode CE overlapping the first anode electrode AE1 may constitute the first light emitting element LD1. The second anode electrode AE2, a portion of the light emitting structure EMS overlapping the second anode electrode AE2, and a portion of the cathode electrode CE overlapping the second anode electrode AE2 may constitute the second light emitting element LD2. The third anode electrode AE3, a portion of the light emitting structure EMS overlapping the third anode electrode AE3, and a portion of the cathode electrode CE overlapping the third anode electrode AE3 may constitute the third light emitting element LD3.

The encapsulation layer TFE is disposed on the cathode electrode CE. The encapsulation layer TFE may prevent oxygen, moisture, and/or the like from permeating to the light emitting element layer LDL.

The optical functional layer OFL is disposed on the encapsulation layer TFE. In embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges. For example, the first to third color filters CF1 to CF3 may pass light of red, green, and blue colors, respectively.

In embodiments, the first to third color filters CF1 to CF3 may partially overlap in the boundary area BDA. In other embodiments, the first to third color filters CF1 to CF3 may be spaced apart from each other, and a black matrix may be provided between the first to third color filters CF1 to CF3.

The lens array LA is disposed on the color filter layer CFL. The lens array LA may include first to third lenses LS1 to LS3 respectively corresponding to the first to third sub-pixels SP1 to SP3. Each of the first to third lenses LS1 to LS3 may improve light output efficiency by redirecting light emitted from the first to third light emitting elements LD1 to LD3 to an intended path.

As described above, the reflective electrode RE may be disposed or buried in the groove GRV of the via layer VIAL. The planarization pattern PLNP may be disposed on the reflective electrode RE in the groove GRV of the via layer VIAL to prevent damage to the reflective electrode RE during a formation process (or a patterning process) of the reflective electrode RE.

In addition, the reflective electrode RE may include the first layer RE_S1, the second layer RE_S2, and the third layer RE_S3 sequentially stacked, each of the first layer RE_S1 and the third layer RE_S3 may include a transparent conductive material, and the second layer RE_S2 may include a metal material, particularly silver (Ag). The third layer RE_S3 may prevent damage to the second layer RE_S2 together with the planarization pattern PLNP.

FIG. 10 is a cross-sectional view illustrating a comparative example of the pixels taken along the line I-I′ of FIG. 6.

Referring to FIGS. 7 and 10, the example of FIG. 10 may be similar to the example of FIG. 7 except for the light emitting element layer LD. Therefore, an overlapping description will not be repeated.

The light emitting element layer LDL is disposed on the via layer VIAL. The light emitting element layer LDL may include first to third reflective electrodes RE1_C to RE3_C, a planarization layer PLNL, the first to third anode electrodes AE1 to AE3, the pixel defining layer PDL, the light emitting structure EMS, and the cathode electrode CE.

The pixel defining layer PDL is disposed on the anode electrode AE. The pixel defining layer PDL may include an opening OP exposing a portion of each anode electrode AE. The pixel defining layer PDL may include an inorganic material. The pixel defining layer PDL is not limited thereto, and the pixel defining layer PDL may include an organic material.

On the via layer VIAL, the first to third reflective electrodes RE1_C to RE3_C are disposed in the first to third sub-pixels SP1 to SP3, respectively. The first to third reflective electrodes RE1_C to RE3_C may include metal materials suitable for reflecting light.

As resolution of the display device increases, a gap between the first to third sub-pixels SP1 to SP3 and a gap GAP between the first to third reflective electrodes RE1_C to RE3_C corresponding thereto may be reduced. That is, the first to third reflective electrodes RE1_C to RE3_C may be formed through an ultrafine patterning process.

For example, the first to third reflective electrodes RE1_C to RE3_C may be formed through a dry etching process, and, to this end, in consideration of manufacturing cost, time, and the like, the first to third reflective electrodes RE1_C to RE3_C may include aluminum (Al) or an alloy thereof. However, a reflectance of aluminum (Al) may be lower than that of silver (Ag), and light output efficiency of the sub-pixel including the first to third reflective electrodes RE1_C to RE3_C of aluminum (Al) may be lower than light output efficiency of the sub-pixel including the first to third reflective electrodes RE1_C to RE3_C of silver (Ag) by about 30%.

Meanwhile, the reflective electrode RE (refer to FIG. 8) according to embodiments of the disclosure may be buried in the via layer VIAL and may be formed through a CMP process rather than a dry etching process. In this case, the reflective electrode RE may include silver (Ag) of which a reflectance is higher than that of aluminum (Al), and light output efficiency of the sub-pixel may be improved.

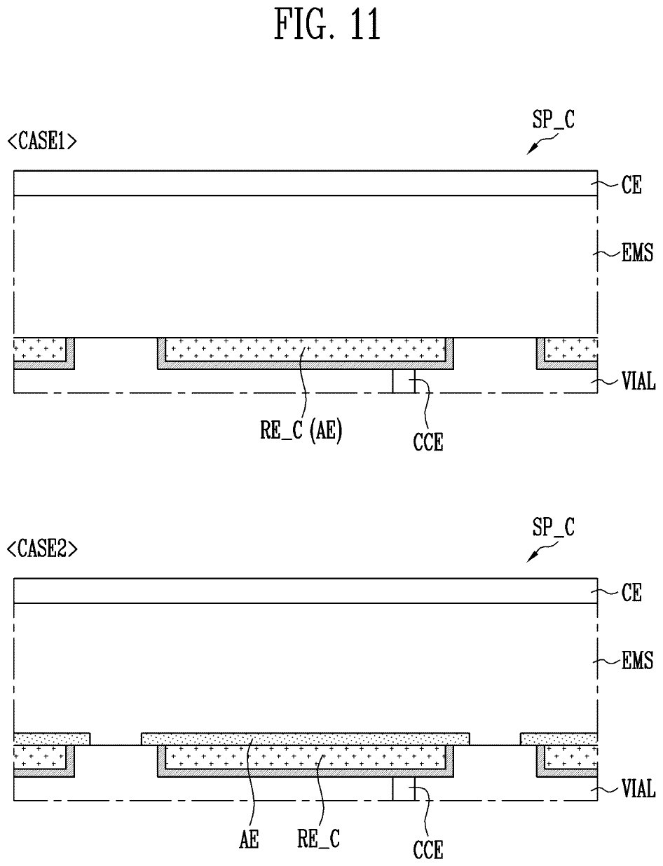

FIG. 11 is a cross-sectional view illustrating a comparative example of the light emitting element layer included in any one of the first to third sub-pixels of FIG. 7.

Referring to FIGS. 8 and 11, in a sub-pixel SP_C of a first case CASE1, the reflective electrode RE_C (or the anode electrode AE) may be buried in the via layer VIAL, and the light emitting structure EMS may be directly disposed on the reflective electrode RE_C.

As in a second case CASE2, the reflective electrode RE_C may be buried in the via layer VIAL, the anode electrode AE may be directly disposed on an upper surface of the reflective electrode RE_C, and the light emitting structure EMS may also be directly disposed on the anode electrode AE. The anode electrode AE and the reflective electrode RE_C may have a non-separation structure (that is, a structure which is not separated from each other).

As in the first case CASE1 and the second case CASE2, when the reflective electrode RE_C is buried in the via layer VIAL, the reflective electrode RE_C may be formed through a CMP process rather than a conventional photolithography process. However, when an upper surface of the reflective electrode RE_C is planarized through the CMP process, damage may occur on the upper surface of the reflective electrode RE_C (for example, on an upper surface of the second layer RE_S2). Silver (Ag) is softer than copper Cu, and a risk of occurrence of a scratch on the reflective electrode RE_C including silver (Ag) during the CMP process is high. When damage, such as a scratch, occurs in the reflective electrode RE_C, a reflectance of the reflective electrode RE_C and light emission efficiency of the sub-pixel SP_C may be reduced.

Meanwhile, in embodiments of the disclosure, the planarization pattern PLNP (refer to FIG. 8) may be disposed on the reflective electrode RE in the groove of the via layer VIAL to prevent damage (for example, a scratch) to the reflective electrode RE during the CMP process.

FIGS. 12A, 12B, 12C, 12D, and 12E are cross-sectional views illustrating a method of manufacturing a display device according to embodiments. FIGS. 12F and 12G are cross-sectional views illustrating a method of forming a via layer of FIG. 12A. The sub-pixel according to the embodiment of FIG. 8 may be manufactured through the method of manufacturing the display device of FIGS. 12A to 12E. For convenience of description, a description overlapping the embodiment of FIG. 8 is omitted.

Referring to FIGS. 8 and 12A, the via layer VIAL (or the base layer) including the protrusion SW may be formed. In other words, a groove GRV and the protrusion SW surrounding the GRV may be formed in the via layer VIAL. The protrusion SW may protrude upward in the boundary area BDA between the sub-pixels SP1 to SP3 (refer to FIG. 7) to form the groove GRV on the upper surface of the via layer VIAL.

In an embodiment, as shown in FIG. 12F, the protrusion SW and a via hole VIAH formed through the via layer VIAL may be formed simultaneously in the via layer VIAL using a half mask MASK. In other words, in a process of forming the via hole VIAH, the protrusion SW may also be formed. Here, the via hole VIAH may be formed in an area corresponding to the connection electrode CCE (refer to FIGS. 7 and 8).

For example, the half mask MASK may include first to third areas A1 to A3 having different transmittances, and a photo process and an etching process using the half mask MASK may be performed on the via layer VIAL. The protrusion SW may be formed in an area corresponding to the first area A1, the via hole VIAH may be formed in an area corresponding to the third area A3, and remaining portions of the via layer VIAL may be formed in an area corresponding to the second area A2.

In an embodiment, as shown in FIG. 12G, the via layer VIAL and the protrusion SW may be formed through different processes. For example, the via layer VIAL may be formed, and then the protrusion SW may be formed through a separate process. In this case, the protrusion SW may include a material different from that of the via layer VIAL.

Referring to FIG. 12B, the reflective electrode layer REL may be formed on the via layer VIAL. The reflective electrode layer REL may be formed entirely on the via layer VIAL.

In an embodiment, the reflective electrode layer REL may include a first layer, a second layer, and a third layer sequentially stacked in correspondence with the reflective electrode RE described with reference to FIG. 8.

Referring to FIG. 12C, the planarization layer PLNL may be formed on the reflective electrode layer REL. The planarization layer PLNL may be formed entirely on the via layer VIAL (or the reflective electrode layer REL). The planarization layer PLNL may have a thickness enough to have an upper surface higher than an upper surface of the protrusion SW.

Referring to FIGS. 12C and 12D, an upper surface of the planarization layer PLNL may be planarized through a polishing process (chemical mechanical polishing (CMP).

A portion of the reflective electrode layer REL and a portion of the planarization layer PLNL disposed on the protrusion SW may be removed through the polishing process. Accordingly, the reflective electrode layer may be separated in the boundary area between the sub-pixels, and the reflective electrode RE, which is a portion of the reflective electrode layer REL disposed in the groove GRV of the via layer VIAL, may be formed.

Referring to FIG. 12E, the anode electrode AE may be formed on the via layer VIAL and the planarization pattern PLNP (or the planarization layer PLNL).

Thereafter, the remaining configurations shown in FIG. 8, for example, the light emitting structure EMS, the cathode electrode CE, and the encapsulation layer TFE, may be sequentially formed. Through this, the display device including the sub-pixel SP according to the embodiment of FIG. 8 may be manufactured.

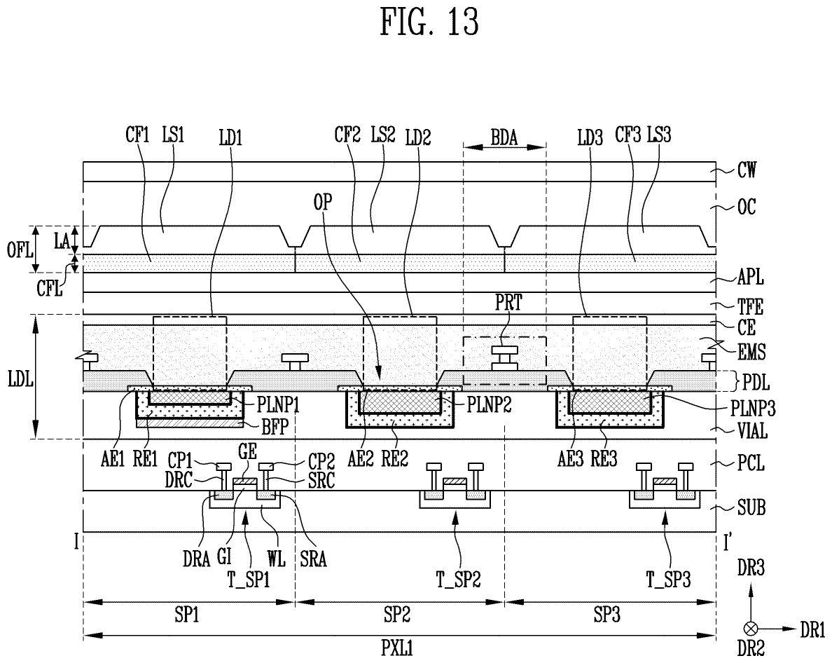

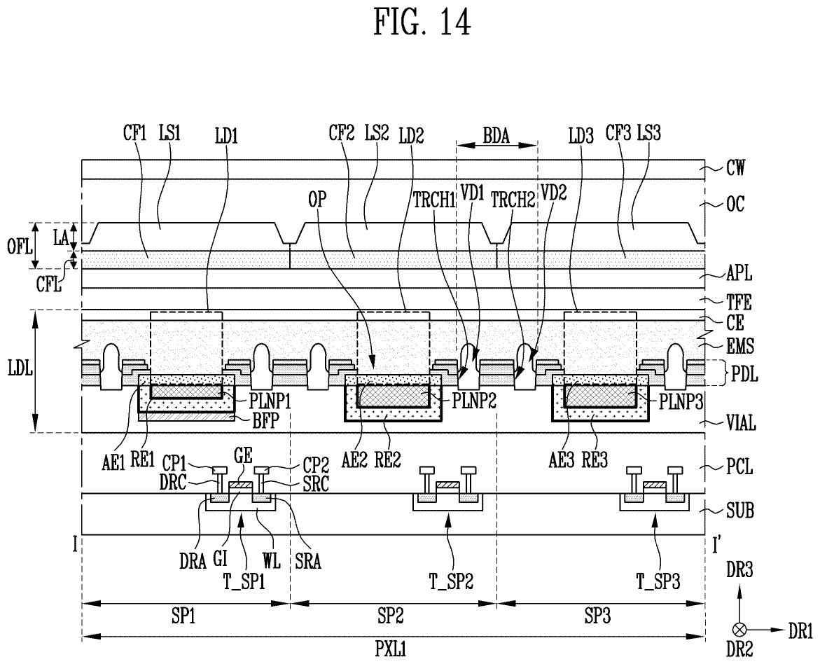

FIG. 13 is a cross-sectional view illustrating an embodiment of the pixel taken along the line I-I′ of FIG. 6. FIG. 14 is a cross-sectional view illustrating an embodiment of the pixel taken along the line I-I′ of FIG. 6. In FIG. 14, an embodiment of a separator is shown, and except for the separator, the embodiment of FIG. 14 may be substantially the same as the embodiment of FIG. 13.

Referring to FIGS. 7, 13, and 14, except for a buffer pattern BFP, the pixel defining layer PDL, and the separator (for example, a protrusion pattern PRT and trenches TRCH1 and TRCH2), the embodiment of FIG. 13 may be substantially the same as or similar to the embodiment of FIG. 7. Therefore, an overlapping description will not be repeated.

In embodiments, the buffer pattern BFP may be disposed under at least one of the first to third reflective electrodes RE1 to RE3. The buffer pattern BFP may be disposed under at least one of the first to third reflective electrodes RE1 to RE3 disposed in the groove of the via layer VIAL.

In an embodiment, the buffer pattern BFP may include a conductive material and may improve an electrical connection characteristic between a corresponding reflective electrode and a circuit element of the pixel circuit layer PCL. For example, the buffer pattern BFP may include titanium (Ti), titanium nitride (TiN), tantalum nitride (TaN), and the like, but embodiments are not limited thereto.

In an embodiment, the buffer pattern BFP may include an insulating material. For example, the buffer pattern BFP may include an inorganic material such as silicon nitride (SiNₓ), silicon carbon nitride, or silicon oxide (SiOₓ), but embodiments are not limited thereto.

According to an embodiment, the buffer pattern BFP may have a multi-layer structure. For example, the buffer pattern BFP may include a conductive layer and an insulating layer.

A height of the third direction DR3 of a corresponding reflective electrode may be adjusted by disposing the buffer pattern BFP. For example, the buffer pattern BFP may be disposed between the first reflective electrode RE1 and the via layer VIAL in the first sub-pixel SP1. In the second sub-pixel SP2, the buffer pattern BFP may not be disposed between the second reflective electrode RE2 and the via layer VIAL, and the second reflective electrode RE2 may be directly disposed on the via layer VIAL. Similarly, in the third sub-pixel SP3, the buffer pattern BFP may not be disposed between the third reflective electrode RE3 and the via layer VIAL, and the third reflective electrode RE3 may be directly disposed on the via layer VIAL.

The first to third reflective electrodes RE1 to RE3 may function as full mirrors, and the cathode electrode CE may function as a half mirror. The light emitted from the light emitting layer of the light emitting structure EMS may be amplified by at least partially reciprocating between a corresponding reflective electrode RE and the cathode electrode CE, and the amplified light may be output through the cathode electrode CE. As described above a distance between each reflective electrode and the cathode electrode CE may be understood as a resonance distance for the light emitted from the light emitting layer of the corresponding light emitting structure EMS.

For example, the first to third sub-pixels SP1 to SP3 may correspond to red, green, and blue, respectively, and a distance between the first reflective electrode RE1 and the cathode electrode CE may be shorter than a distance between the second reflective electrode RE2 and the cathode electrode CE.

The first sub-pixel SP1 may have a resonance distance shorter than that of the second and third sub-pixels SP2 and SP3 due to the buffer pattern BFP. The resonance distance adjusted as described above may allow light of a specific wavelength range (for example, red color) to be effectively and efficiently amplified. Accordingly, the first sub-pixel SP1 may effectively and efficiently output light of a corresponding wavelength range.

In FIG. 13, the buffer pattern BFP is provided to the first sub-pixel SP1 and is not provided to the second and third sub-pixels SP2 and SP3, but embodiments are not limited thereto. The buffer pattern may also be provided to at least one of the second and third sub-pixels SP2 and SP3 to adjust the resonance distance of at least one of the second and third sub-pixels SP2 and SP3. For example, the buffer pattern BFP may also be provided to the second sub-pixel SP2, and the resonance distance of the second sub-pixel SP2 may be adjusted. For example, the distance between the second reflective electrode RE2 and the cathode electrode CE may be the same as the distance between the first reflective electrode RE1 and the cathode electrode CE, and the distance between the third reflective electrode RE3 and the cathode electrode CE may be longer than the distance between the first reflective electrode RE1 and the cathode electrode CE.

The pixel defining layer PDL is disposed on the anode electrode AE. The pixel defining layer PDL may include an opening OP exposing a portion of each anode electrode AE. In embodiments, the pixel defining layer PDL may include a plurality of stacked inorganic layers. For example, the pixel defining layer PDL may include silicon oxide (SiOₓ) and silicon nitride (SiNₓ). In other embodiments, the pixel defining layer PDL may include an organic material. However, a material of the pixel defining layer PDL is not limited thereto.

The light emitting structure EMS may fill the opening OP of the pixel defining layer PDL and may be disposed entirely on the pixel defining layer PDL. In other words, the light emitting structure EMS may extend across the first to third sub-pixels SP1 to SP3. In this case, at least some of the layers in the light emitting structure EMS may be disconnected or bent at the boundaries between the first to third sub-pixels SP1 to SP3.

However, embodiments are not limited thereto. For example, portions of the light emitting structure EMS corresponding to the first to third sub-pixels SP1 to SP3 may be separated from each other, and each of the portions may be disposed in the opening OP of the pixel defining layer PDL.

The separator may be provided in the boundary area BDA between neighboring sub-pixels.

The separator may cause formation of a discontinuity in the light emitting structure EMS at the boundary area BDA. For example, the light emitting structure EMS may be disconnected or bent at the boundary area BDA due to the separator.

The separator may be provided in or on the pixel defining layer PDL.

In an embodiment, the pixel defining layer PDL may include the protrusion pattern PRT as the separator in the boundary area BDA.

As shown in FIG. 13, the protrusion pattern PRT additionally stacked on the pixel defining layer PDL may be provided in the boundary area BDA. A width of the protrusion pattern PRT may become wider in an upper portion. For example, the protrusion pattern PRT may include inorganic insulating patterns. A width of the uppermost inorganic insulating pattern among the inorganic insulating patterns may be greater than a width of the inorganic insulating pattern disposed immediately thereunder. For example, in the boundary area BDA, first to third inorganic insulating patterns may be sequentially stacked on the pixel defining layer PDL, and the uppermost third inorganic insulating pattern may have a width greater than that of the second inorganic insulating pattern. For example, the protrusion pattern PRT may have a “T”-shaped or “I”-shaped cross-section in the boundary area BDA. According to a shape of the protrusion pattern PRT, a plurality of layers included in the light emitting structure EMS may be at least partially disconnected or bent in the boundary area BDA.

The separator may be variously modified and provided so that the light emitting structure EMS may have a discontinuous portion in the boundary area BDA. In embodiments, the pixel defining layer PDL may include one or more trenches TRCH1 and TRCH2 as the separator in the boundary area BDA.

As shown in FIG. 14, the one or more trenches TRCH1 and TRCH2 may be formed through the pixel defining layer PDL and may partially formed through the via layer VIAL. In other embodiments, the one or more trenches TRCH1 and TRCH2 may at least partially formed through the via layer VIAL, and a portion of the pixel defining layer PDL in the one or more trenches TRCH1 and TRCH2 may be removed.

For example, two trenches TRCH1 and TRCH2 separated from each other may be provided in the boundary area BDA. For example, the first trench TRCH1 and the second trench TRCH2 may be disposed in the boundary area BDA between the second sub-pixel SP2 and the third sub-pixel SP3, the first trench TRCH1 may be disposed along an edge of the second sub-pixel SP2, and the second trench TRCH2 may be disposed along an edge of the third sub-pixel SP3. When the trenches TRCH1 and TRCH2 are separated from each other, a width of each of the trenches TRCH1 and TRCH2 may be maintained constant, and the discontinuous portion of the light emitting structure EMS may become uniform in the boundary area BDA. When the trenches TRCH1 and TRCH2 are connected, a width of a connection portion of the trenches TRCH1 and TRCH2 may become larger than a width of another portion, the discontinuous portion of the light emitting structure EMS may become uneven, and a characteristic of the light emitting structure EMS may become uneven.

In FIG. 14, the two trenches TRCH1 and TRCH2 are provided in the boundary area BDA. However, embodiments are not limited thereto. For example, the pixel defining layer PDL may include one trench in the boundary area BDA. Alternatively, the pixel defining layer PDL may include three or more trenches in the boundary area BDA.

Due to the first and second trenches TRCH1 and TRCH2 disposed in the boundary area BDA, discontinuous portions such as a first void VD1 and a second void VD2 may be formed in the light emitting structure EMS. A portion of a plurality of layers stacked in the light emitting structure EMS may be disconnected or bent by the first and second voids VD1 and VD2. For example, at least one charge generation layer included in the light emitting structure EMS may be disconnected in the first and second voids VD1 and VD2. As described above, portions of the light emitting structure EMS included in the first to third sub-pixels SP1 to SP3 may be at least partially separated due to the first and second trenches TRCH1 and TRCH2.

In FIG. 14, in the boundary area BDA, the first and second voids VD1 and VD2 are formed in the light emitting structure EMS, but this is exemplary, and embodiments are not limited thereto. For example, in the boundary area BDA, a valley of a concave shape may be formed in the light emitting structure EMS. According to shapes of the first and second trenches TRCH1 and TRCH2, discontinuous portions formed in the light emitting structure EMS may be variously changed.

In embodiments, the light emitting structure EMS may be formed through a process of vacuum deposition, inkjet printing, and the like. In this case, the same materials as the light emitting structure EMS may be positioned on bottom surfaces of the first and second trenches TRCH1 and TRCH2 disposed adjacent to the via layer VIAL.

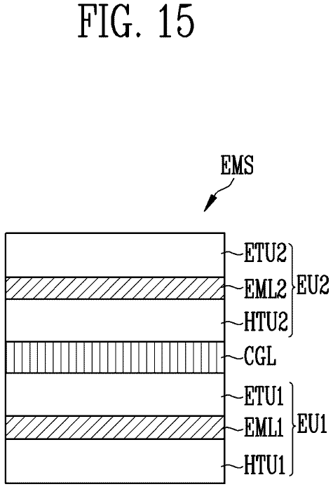

FIG. 15 is a cross-sectional view illustrating an embodiment of the light emitting structure included in any one of the first to third light emitting elements of FIG. 7.

Referring to FIG. 15, the light emitting structure EMS may have a tandem structure in which first and second light emitting units EU1 and EU2 are stacked. The light emitting structure EMS may be configured substantially the same in each of the first to third light emitting elements LD1 to LD3 of FIG. 15.

Each of the first and second light emitting units EU1 and EU2 may include at least one light emitting layer that generates light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU1 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer, and may further include a hole buffer layer, an electron blocking layer, and the like if necessary. The first and second hole transport units HTU1 and HTU2 may have configurations equal to each other or different from each other.

Each of the first and second electron transport units ETU1 and ETU2 may include at least one of an electron injection layer and an electron transport layer, and may further include an electron buffer layer, a hole blocking layer, and the like if necessary. The first and second electron transport units ETU1 and ETU2 may have configurations equal to each other or different from each other.

A connection layer, which may be provided in a form of a charge generation layer CGL, may be disposed between the first light emitting unit EU1 and the second light emitting unit EU2 to connect the first light emitting unit EU1 and the second light emitting unit EU2 to each other. In embodiments, the charge generation layer CGL may have a stack structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide metal, or a combination thereof. However, embodiments are not limited thereto.

In embodiments, the first light emitting layer EML1 and the second light emitting layer EML2 may generate light of different colors. Light emitted from each of the first and second light emitting layers EML1 and EML2 may be mixed and viewed as white light. For example, the first light emitting layer EML1 may generate light of a blue color, and the second light emitting layer EML2 may generate light of a yellow color. In embodiments, the second light emitting layer EML2 may include a structure in which a first sub light emitting layer configured to generate light of a red color and a second sub light emitting layer configured to generate light of a green color are stacked. The light of the red color and the light of the green color may be mixed, and thus the light of the yellow color may be provided. In this case, an intermediate layer configured to perform a function of transporting holes and/or blocking transport of electrons may be further disposed between the first and second sub light emitting layers.

In other embodiments, the first light emitting layer EML1 and the second light emitting layer EML2 may generate light of the same color.

The light emitting structure EMS may be formed through a method such as vacuum deposition or inkjet printing, but embodiments are not limited thereto.

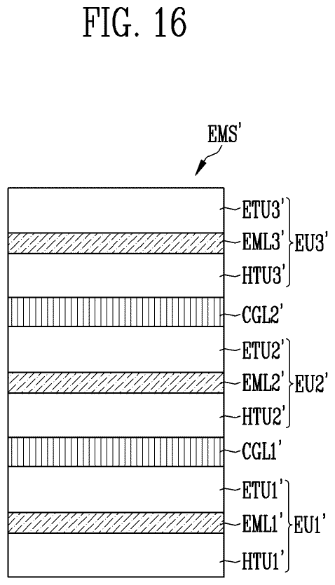

FIG. 16 is a cross-sectional view illustrating an embodiment of the light emitting structure included in any one of the first to third light emitting elements of FIG. 7.

Referring to FIG. 16, the light emitting structure EMS' may have a tandem structure in which first to third light emitting units EU1′ to EU3′ are stacked. The light emitting structure EMS' may be configured substantially the same in each of the first to third light emitting elements LD1 to LD3 in FIG. 7.

Each of the first to third light emitting units EU1′ to EU3′ may include a light emitting layer that generates light according to an applied current. The first light emitting unit EU1′ may include a first light emitting layer EML1′, a first electron transport unit ETU1′, and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and a hole transport layer, and may further include a hole buffer layer, an electron blocking layer, and the like if necessary. The first to third hole transport units HTU1′ to HTU3′ may have configurations equal to each other or different from each other.

Each of the first to third electron transport units ETU1′ to ETU3′ may include at least one of an electron injection layer and an electron transport layer, and may further include an electron buffer layer, a hole blocking layer, and the like if necessary. The first to third electron transport units ETU1′ to ETU3′ may have configurations equal to each other or different from each other.

A first charge generation layer CGL1′ is disposed between the first light emitting unit EU1′ and the second light emitting unit EU2′. A second charge generation layer CGL2′ is disposed between the second light emitting unit EU2′ and the third light emitting unit EU3′.

In embodiments, the first to third light emitting layers EML1′ to EML3′ may generate light of different colors. Light emitted from each of the first to third light emitting layers EML1′ to EML3′ may be mixed and viewed as white light. For example, the first light emitting layer EML1′ may generate light of a blue color, the second light emitting layer EML2′ may generate light of a green color, and the third light emitting layer EML3′ may generate light of a red color.

In other embodiments, two or more of the first to third light emitting layers EML1′ to EML3′ may generate light of the same color.

Different from the embodiments of FIGS. 14 and 15, the light emitting structure EMS of FIG. 7 may include one light emitting unit in each of the first to third light emitting elements LD1 to LD3. The light emitting unit included in each of the first to third light emitting elements LD1 to LD3 may be configured to emit light of different colors. For example, the light emitting unit of the first light emitting element LD1 may emit the light of the red color, the light emitting unit of the second light emitting element LD2 may emit the light of the green color, and the light emitting unit of the third light emitting element LD3 may emit the light of the blue color. In this case, different from that shown in FIGS. 14 and 15, the light emitting units of the first to third sub-pixels SP1 to SP3 may be separated from each other, and each of them may be disposed in the opening OP of the pixel defining layer PDL. In this case, at least a portion of the color filters CF1 to CF3 may be omitted.

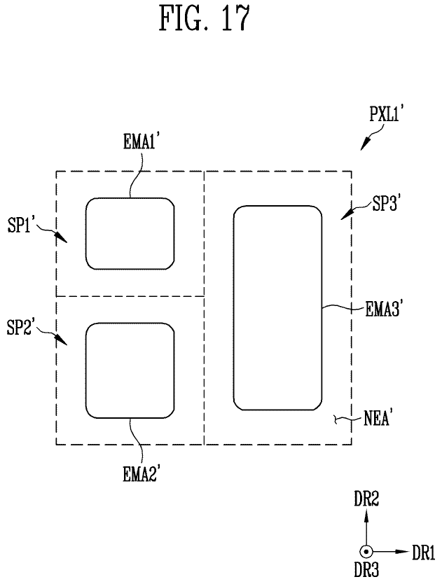

FIG. 17 is a plan view illustrating an embodiment of any one of the pixels of FIG. 5.

Referring to FIG. 17, a first pixel PXL1′ may include first to third sub-pixels SP1′ to SP3′.

The first sub-pixel SP1′ may include a first emission area EMA1′ and a non-emission area NEA′ around the first emission area EMA1′. The second sub-pixel SP2′ may include a second emission area EMA2′ and a non-emission area NEA′ around the second emission area EMA2′. The third sub-pixel SP3′ may include a third emission area EMA3′ and a non-emission area NEA′ around the third emission area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have the area greater than that of the first sub-pixel SP1′, and the third sub-pixel SP3′ may have the area greater than that of the second sub-pixel SP2′. Accordingly, the second emission area EMA2′ may have the area greater than that of the first emission area EMA1′, and the third emission area EMA3′ may have the area greater than that of the second emission area EMA2′. However, embodiments are not limited thereto. For example, the first and second sub-pixels SP1′ and SP2′ may have substantially the same area, and the third sub-pixel SP3′ may have the area greater than that of each of the first and second sub-pixels SP1′ and SP2′. As described above, the areas of the first to third sub-pixels SP1′ to SP3′ may be variously modified according to embodiments.

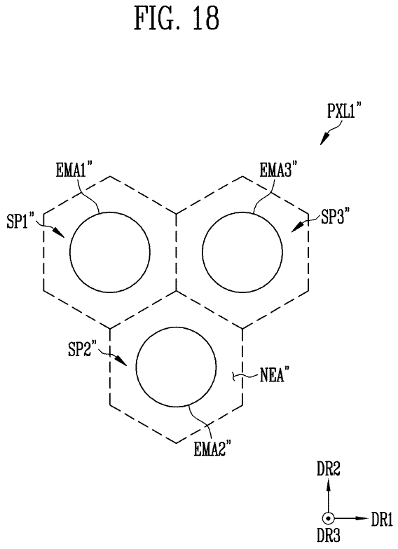

FIG. 18 is a plan view illustrating an embodiment of any one of the pixels of FIG. 5.

Referring to FIG. 18, a first sub-pixel SP1″ may include a first emission area EMA1″ and a non-emission area NEA″ around the first emission area EMA1″. A second sub-pixel SP2″ may include a second emission area EMA2″ and a non-emission area NEA″ around the second emission area EMA2″. A third sub-pixel SP3″ may include a third emission area EMA3″ and a non-emission area NEA″ around the third emission area EMA3″.

The first to third sub-pixels SP1″ to SP3″ may have polygonal shapes when viewed in the third direction DR3. For example, shapes of the first to third sub-pixels SP1″ to SP3″ may be hexagonal shapes as shown in FIG. 18.

The first to third emission areas EMA1″ to EMA3″ may have circular shapes when viewed in the third direction DR3. However, embodiments are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be disposed in a direction inclined by an acute angle (or a diagonal direction) from the second direction DR2 with respect to the first sub-pixel SP1″.

An arrangement of the sub-pixels shown in FIGS. 6, 17, and 18 is exemplary, and embodiments are not limited thereto. Each pixel may include two or more sub-pixels, the sub-pixels may be arranged in various methods, each of the sub-pixels may have various shapes, and each of emission areas of each of the sub-pixels may also have various shapes.

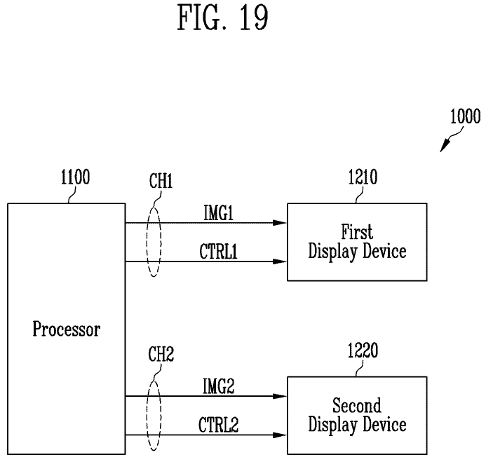

FIG. 19 is a diagram illustrating an embodiment of a display system.

Referring to FIG. 19, the display system 1000 may include a processor 1100 and one or more display devices 1210 and 1220.

The processor 1100 may perform various tasks and calculations. In embodiments, the processor 1100 may include an application processor, a graphic processor, a microprocessor, a central processing unit (CPU), and the like. The processor 1100 may be connected to other components of the display system 1000 through a bus system and may control the other components.

In FIG. 19, the display system 1000 includes the first and second display devices 1210 and 1220. The processor 1100 may be connected to the first display device 1210 through a first channel CH1 and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 1000 may include a computing system providing an image display function, such as a portable computer, a mobile phone, a smart phone, a tablet personal computer (PC), a smart watch, a watch phone, a portable multimedia player (PMP), a navigation device, and an ultra-mobile personal computer (UMPC). In addition, the display system 1000 may include at least one of a head mounted display (HMD) device, a virtual reality (VR) device, a mixed reality (MR) device, and an augmented reality (AR) device.

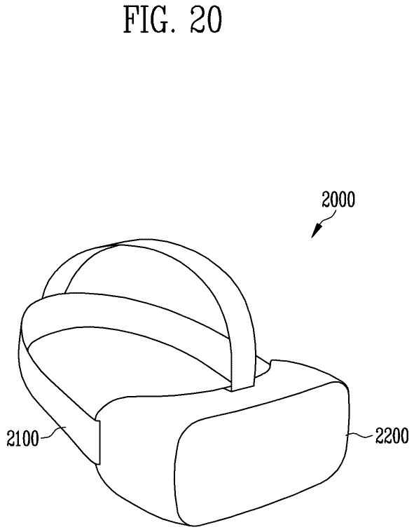

FIG. 20 is a perspective view illustrating an application example of the display system of FIG. 19.

Referring to FIG. 20, the display system 1000 of FIG. 19 may be applied to a head mounted display device 2000. The head mounted display device 2000 may be a wearable electronic device that may be worn on a user's head.

The head mounted display device 2000 may include a head mount band 2100 and a display device accommodation case 2200. The head mount band 2100 may be connected to the display device accommodation case 2200. The head mount band 2100 may include a horizontal band and/or a vertical band for fixing the head mounted display device 2000 to the user's head. The horizontal band may be configured to surround a side portion of the user's head, and the vertical band may be configured to surround an upper portion of the user's head. However, embodiments are not limited thereto. For example, the head mount band 2100 may be implemented in a glasses frame form, a helmet form, or the like.

The display device accommodation case 2200 may accommodate the first and second display devices 1210 and 1220 of FIG. 19. The display device accommodation case 2200 may further accommodate the processor 1100 of FIG. 19.

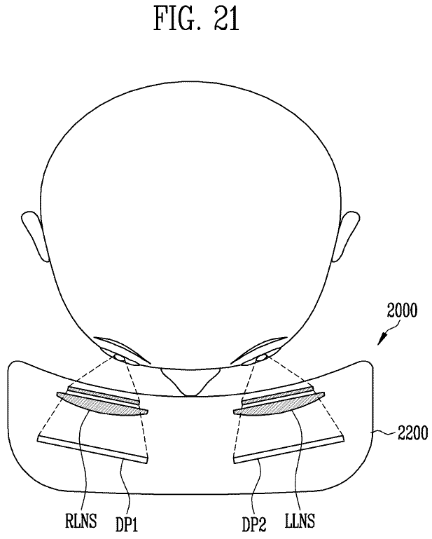

FIG. 21 is a diagram illustrating the head mounted display device worn by a user of FIG. 20.

Referring to FIG. 21, a head mounted display device 2000 (or the wearable electronic device) may include a display panel that emits light and a lens unit disposed on the display panel (or on an emission path of light). The display panel may include a first display panel DP1 of the first display device 1210 and a second display panel DP2 of the second display device 1220. The lens unit may further include one or more lenses LLNS and RLNS.

Within the display device accommodation case 2200, the right eye lens RLNS may be disposed between the first display panel DP1 and a user's right eye. Within the display device accommodation case 2200, the left eye lens LLNS may be disposed between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed to the user.

Although specific embodiments and application examples are described herein, other embodiments and modifications may be derived from the above description. Therefore, the spirit of the disclosure is not limited to such embodiments, and extends to the scope of the claims set forth below, various obvious modifications, and equivalents.

What is claimed is:

1. A display device comprising:
a base layer including a groove surrounded by a protrusion which is disposed in a boundary area between sub-pixels;
a reflective electrode disposed on the base layer in the groove;
a planarization pattern disposed on the reflective electrode in the groove;
an anode disposed on the planarization pattern and contacting the reflective electrode; and
a light emitting layer disposed on the anode.

2. The display device of claim 1, wherein a portion of the reflective electrode covers a side surface of the protrusion, and
wherein an upper surface of the portion of the reflective electrode, an upper surface of the planarization pattern, and an upper surface of the protrusion are positioned on the same plane.

3. The display device of claim 2, wherein the upper surface of the portion of the reflective electrode, the upper surface of the planarization pattern, and the upper surface of the protrusion are formed simultaneously through a polishing process.

4. The display device of claim 2, wherein the anode is directly disposed on the portion of the reflective electrode and the planarization pattern, and directly contacts the portion of the reflective electrode.

5. The display device of claim 2, wherein the reflective electrode includes a first layer, a second layer, and a third layer sequentially stacked,
wherein each of the first layer and the third layer includes a transparent conductive material, and
wherein the second layer includes a metal material.

6. The display device of claim 5, wherein the second layer includes silver.

7. The display device of claim 5, wherein the anode directly contacts the second layer of the reflective electrode.

8. The display device of claim 1, wherein the light emitting layer directly contacts the base layer in the boundary area between the sub-pixels.

9. The display device of claim 1, wherein the planarization pattern includes an inorganic material, and
wherein the anode includes a transparent conductive material.

10. The display device of claim 1, wherein the reflective electrode surrounds the planarization pattern in a plan view, and
wherein the anode covers the reflective electrode.

11. The display device of claim 1, further comprising:
a buffer pattern disposed under the reflective electrode in the groove.

12. The display device of claim 1, further comprising:
a pixel defining layer disposed on the base layer in the boundary area between the sub-pixels; and
a protrusion pattern disposed on the pixel defining layer and having a width that becomes wider toward an upper portion.

13. The display device of claim 1, further comprising trenches formed in the base layer in the boundary area,
wherein the trenches are separated from each other.

14. A wearable display device comprising:
a display panel that emits light; and
at least one lens disposed on the display panel,
wherein the display panel comprises:
a base layer including a groove surrounded by a protrusion which is disposed in a boundary area between sub-pixels;
a reflective electrode disposed on the base layer in the groove;
a planarization pattern disposed on the reflective electrode in the groove;
an anode disposed the planarization pattern and contacting the reflective electrode; and
a light emitting layer disposed on the anode.

15. A method of manufacturing a display device, the method comprising:
forming a groove in a base layer, the groove being surrounded by a protrusion which is disposed in a boundary area between sub-pixels;
forming a reflective electrode layer on the base layer;
forming a planarization layer on the reflective electrode layer;
removing a portion of the reflective electrode layer and a portion of the planarization layer on the protrusion through a polishing process;
forming an anode on the base layer and the planarization layer; and
forming a light emitting layer on the anode.

16. The method of claim 15, wherein the forming the groove in the base layer comprises simultaneously forming the groove and a via hole in the base layer using a half tone mask.

17. The method of claim 15, wherein the forming the groove in the base layer comprises:
forming the base layer; and
forming the groove in the base layer.

18. The method of claim 15, wherein the reflective electrode layer is separated in the boundary area between the sub-pixels by the polishing process to form a reflective electrode which is disposed in the groove.

19. The method of claim 15, wherein the forming the reflective electrode layer comprises sequentially forming a first layer, a second layer, and a third layer on the base layer,
wherein each of the first layer and the third layer includes a transparent conductive material, and
wherein the second layer includes a metal material.

20. The method of claim 19, wherein the second layer includes silver.
